(19) United States
(12) Patent Application Publication
(10) Pub. No.: US 2019/0296166 A1
(43) Pub. Date: Sep. 26, 2019

(54) THIN FLEXIBLE MODULES

(71) Applicant: MiaSolé Hi-Tech Corp., Santa Clara, CA (US)

(72) Inventors: John Huang, San Jose, CA (US); Jason Stephen Corneille, San Jose, CA (US); Feng Xie, San Jose, CA (US); Richard Weinberg, Cupertino, CA (US)

(21) Appl. No.: 15/934,751

(22) Filed: Mar. 23, 2018

(51) Int. Cl. H01L 31/0392; H01L 31/05

(52) U.S. Cl. CPC H01L 31/03926; H01L 31/0508; H01L 31/0512

(57) ABSTRACT

Provided herein are ultra-thin flexible photovoltaic modules. The flexible modules meet UL and IEC safety requirements without needing one or more encapsulant layers. The no-encapsulant design reduces material usage and associated cost and eliminates thermal and mechanical stress imparted by the encapsulant. In some embodiments, a flexible module includes photovoltaic cells enclosed between sealing sheets, wires partially embedded in wire carriers and disposed such that the wires interconnect the photovoltaic cells. The wire carriers include multiple polymeric layers. Adhesive from module components such as sealing sheets and wire carriers bonds the components together.

### BACKGROUND

Photovoltaic technology is being rapidly adopted to generate electricity from solar energy, both for local use and for supplying power to electrical grids. Photovoltaic systems may be implemented on structures, such as buildings and houses. In addition, light weight photovoltaic modules are now being adopted for transportation applications such as trucks, cars, and boats. Photovoltaic cells are the basic units of such systems. One or more photovoltaic cells are typically arranged into a photovoltaic module, which may be then used to form a photovoltaic array.

### SUMMARY

One aspect of the disclosure relates to a photovoltaic module having a transparent flexible top sheet; a flexible bottom sheet; a plurality of photovoltaic cells disposed between the transparent flexible top sheet and flexible bottom sheet; and a plurality of individual wire assemblies overlaying the photovoltaic cells to interconnect the photovoltaic cells, wherein there is no encapsulant separating the plurality of individual wire assemblies from the transparent flexible top sheet and the flexible bottom sheet.

In some embodiments, each of the individual wire assemblies comprises a layer of a first polymeric material having a melting temperature greater than 160° C. between second and third thermoplastic polymeric layers having melting temperatures less than 140° C. In some embodiments, the second and third thermoplastic polymeric layers are polyolefins. In some embodiments, at least some of the individual wire assemblies directly contact the transparent flexible top sheet. In some embodiments, at least some of the individual wire assembles directly contact the flexible bottom sheet. In some embodiments, the module includes no void spaces having a cross-sectional area of greater than 50 mm2.

In some embodiments, the flexible bottom sheet is a multi-layer flexible sheet, having an innermost layer that faces the photovoltaic cells and an outermost layer that forms an outermost layer of the photovoltaic module. In some embodiments, the innermost layer is a thermoplastic polymeric layer having a melting temperature less than 140° C. In some embodiments, the innermost layer is between 50 microns and 150 microns thick. In some embodiments, at least some of the innermost layer directly contacts one or more individual wire carriers. In some embodiments, the module has a thickness of no more than 0.4 mm.

Another aspect of the disclosure relates to a photovoltaic module having a transparent flexible top sheet; a flexible bottom sheet comprising an innermost adhesive layer having a thickness of between 12.5 and 150 microns; a plurality of photovoltaic cells disposed between the transparent flexible top sheet and flexible bottom sheet; and a plurality of individual wire assemblies overlaying the photovoltaic cells to interconnect the photovoltaic cells, wherein there innermost layer of the flexible bottom sheet directly contacts at least some of the plurality of individual wire assemblies.

These and other aspects are described further below with reference to the drawings.

### BRIEF DESCRIPTION OF THE DRAWINGS

FIG. 1 depicts a top view of an example flexible photovoltaic module.

FIG. 2 depicts a cross-sectional side view of the module 100 of FIG. 1.

FIG. 3 depicts an example of a photovoltaic cell and wire assembly according to certain embodiments.

FIG. 4 depicts interconnection of photovoltaic cells using wire assemblies according to certain embodiments.

FIG. 5 depicts top and bottom views of an example wire assembly according to certain embodiments.

FIGS. 6 and 7 depict cross-sectional views of examples of wire assemblies according to certain embodiments.

FIG. 8a depicts a cross-sectional view of an example of a multi-layer flexible top sheet.

FIG. 8b depicts a cross-sectional view of an example of a multi-layer flexible bottom sheet.

FIG. 9a depicts a schematic cross-sectional view of a material layer stack of a flexible module having no encapsulant layers.

FIG. 9b depicts an annotated cross-sectional image of a portion of a flexible module having no encapsulant layers.

FIG. 10 depicts a schematic of an exploded view of a portion of a module stack according to certain embodiments.

FIG. 11a depicts a schematic cross-sectional view of a material layer stack of a flexible module having encapsulant layers.

FIG. 11b depicts an annotated cross-sectional image of a portion of a flexible module having encapsulant layers.

### DETAILED DESCRIPTION

In the following description, numerous specific details are set forth in order to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Flexible photovoltaic modules are made of flexible materials that allow these modules to bend and conform to various non-planar installation surfaces. Such modules can include two flexible sealing sheets and a set of flexible photovoltaic cells sealed between these sheets. Flexible modules are easier to handle and install than their rigid glass counterparts. For example, flexible modules are less susceptible to damage when dropped or stepped on. Further, such modules may be positioned directly onto supporting surfaces without any intermediate mounting hardware. Flexible materials used for constructing photovoltaic modules may be easier to cut or otherwise shape to fit these modules into available installation areas. Flexible sealing sheets may be bonded directly to various installation surfaces, such as rooftop polymer membranes, and may be used for additional protection of these surfaces after installation.

Flexible photovoltaic modules enable applications that are not compatible with rigid modules. For example, flexible modules may be used on substantially horizontal rooftops, which are common on commercial buildings. Horizontal rooftops use different roofing materials and are subject to different environmental conditions than the typically sloped rooftops of residential buildings. Freezing and thawing cycles of ice and snow on horizontal rooftops can cause substantial thermal and mechanical stresses to be exerted on rooftop structures. Further, flat rooftops may have greater temperature fluctuations because of their construction materials. Photovoltaic modules used on horizontal rooftops may be subject to stresses associated with freeze and thaw cycles and temperature fluctuations.

Provided herein are ultra-thin flexible photovoltaic modules. The flexible modules meet UL and IEC safety requirements without needing one or more encapsulant layers. The no-encapsulant design reduces material usage and associated cost and eliminates thermal and mechanical stress imparted by the encapsulant. In some embodiments, a flexible module includes photovoltaic cells enclosed between sealing sheets, wires partially embedded in wire carriers and disposed such that the wires interconnect the photovoltaic cells. The wire carriers, also referred to as decals, include multiple polymeric layers. Adhesive from module components such as sealing sheets and wire carriers bonds the components together.

As used herein, the term “flexible” with regard to a flexible photovoltaic module or component thereof means that the flexible photovoltaic module or component is capable of being flexed by an average person using moderate force without significant damage to the photovoltaic cells, for instance being elastically deformed without causing damage to the photovoltaic module and without plastically deforming the flexible photovoltaic module.

The terms “top” and “front” as used with respect to photovoltaic modules and components thereof are used interchangeably to denote the light-incident side of a module or photovoltaic cell. Similarly, the terms “bottom” and “back” are used interchangeably to denote the opposite side.

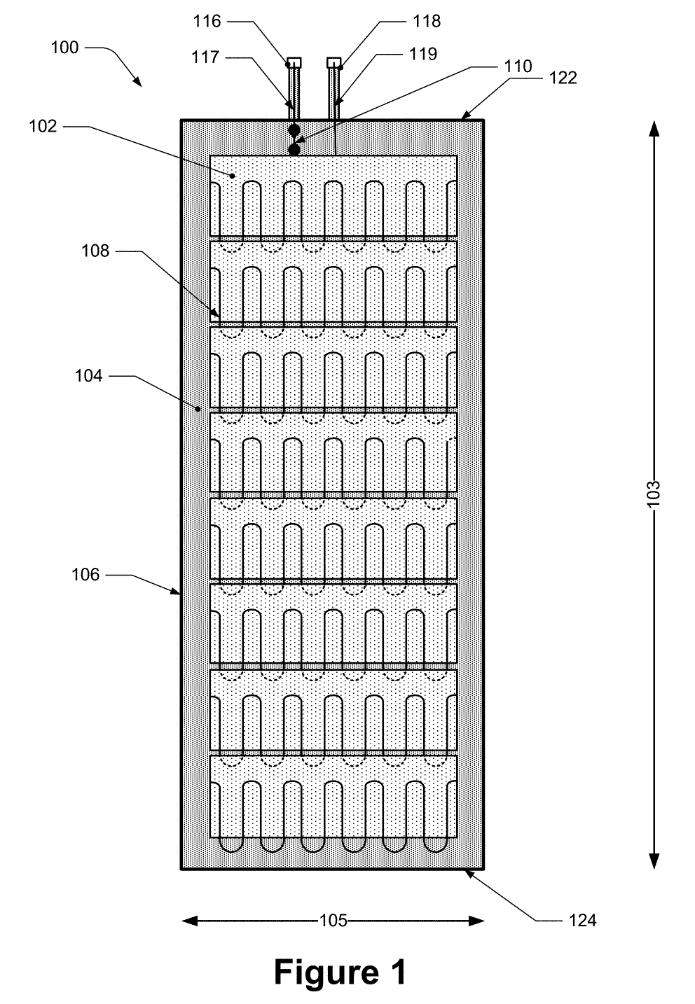

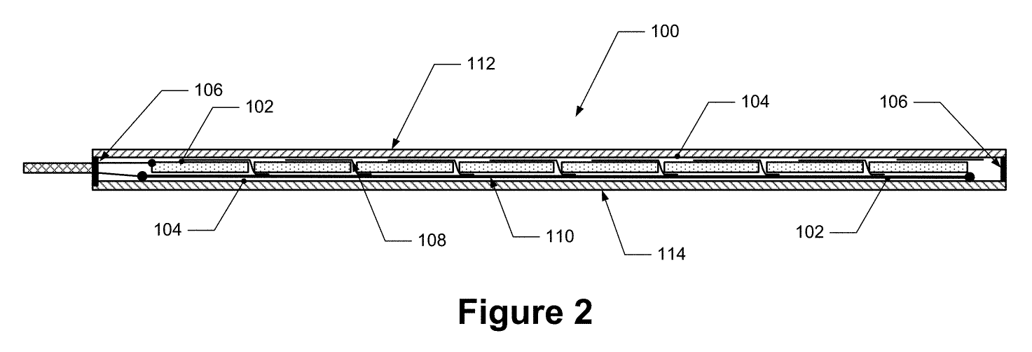

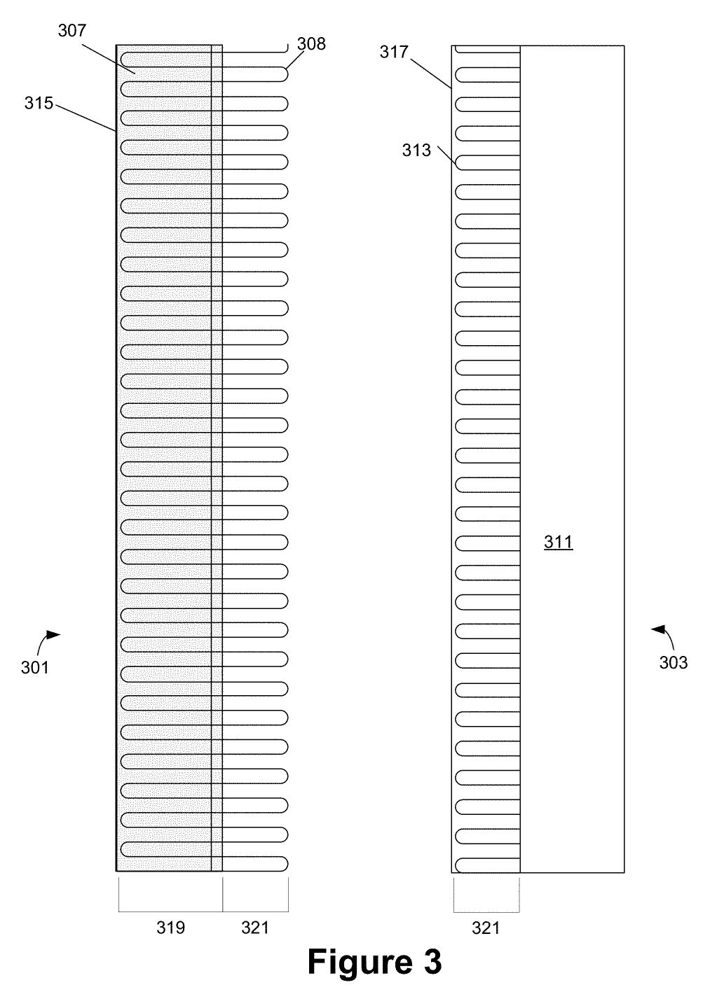

An example embodiment of a flexible photovoltaic module that is the subject of the present disclosure will now be discussed. An overview of the example embodiment is provided below with respect to FIGS. 1 and 2. Further details of the wire carriers and material stacks of the flexible photovoltaic module are provided with respect to FIGS. 3-9b.

FIG. 1 depicts a top view of an example flexible photovoltaic module 100 while FIG. 2 depicts a cross-sectional side view of the module 100 of FIG. 1. As can be seen in FIG. 1, the example flexible photovoltaic module 100 (referred to herein as “module 100”) includes a flexible top sheet (not labeled in FIG. 1, 112 in FIG. 2), a flexible bottom sheet (not labeled in FIG. 1, 114 in FIG. 2), a sealed space 104, eight photovoltaic cells 102 positioned within the sealed space 104, an edge seal 106, eight wires 108, and a bus bar 110. The bus bar is generally positioned between the flexible bottom sheet and the photovoltaic cells 102; it is depicted in FIG. 1 as a heavy dotted line. The module 100 includes a length 103 in the z-axis of FIG. 1 and a width 105 in the x-axis of FIG. 1. The y-axis of the module 100 is at a direction perpendicular to the flexible top sheet 112 and the flexible bottom sheet 114 as seen in FIG. 2, and represents a thickness of the module 100. These axes are applicable throughout the Figures.

In FIG. 2, the flexible top sheet 112 and the flexible bottom sheet 114 can be seen vertically offset from each other in the y-axis, the sealed space 104 is located between the flexible top and flexible bottom sheets 112 and 114, the photovoltaic cells 102 are positioned within the sealed space 104. As seen in FIG. 2, two portions of the edge seal 106, shown at each end of the module 100, span between the flexible top sheet 112 and the flexible bottom sheet 114 and form a part of exterior edge surfaces of the module 100. Here, the flexible top sheet 112 and the flexible bottom sheet 114 are substantially the same size (same length and width) and are substantially aligned with each other. Substantially here means within +/−5% in size and alignment.

The sealed space 104, identified in dark shading in FIGS. 1 and 2, is in between the flexible top sheet 112 and the flexible bottom sheet 114. This sealed space 104 may be considered a plenum that is bounded, in whole or in part, by the flexible top sheet 112, the flexible bottom sheet 114, and the edge seal 106. The edge seal 106 is depicted in FIG. 1 as the edge around the module 100 (i.e., the solid black edge of the module 100). The edge seal 106 may extend along one or more edges of, and may span between, the first sheet and the second sheet; it may also form a portion of the exterior surface of the module 100. It is understood that the edge seal 106 may also form a portion of the exterior surface of the module 100 as well as define a boundary of the sealed space 104. Within the sealed space 104, is a photovoltaic area, i.e., the area that is defined by the boundaries of the interconnected photovoltaic cells.

The flexible top sheet 112 is a light-facing sheet. The flexible top sheet 112 and flexible bottom sheet 114 may be sealing sheets that include flexible materials, such as thermal polymer olefins (TPO) and non-olefin thermoplastic polymers. Examples of flexible top sheet and bottom sheet materials include polyethylene, polyethylene terephthalate (PET), polypropylene, polybutylene, polybutylene terephthalate (PBT), polyphenylene oxide (PPO), polyphenylene sulfide (PPS), polyphenylene oxide (PPO), polystyrene, polycarbonate (PC), ethylene-vinyl acetate (EVA), fluoropolymers (e.g., polyvinyl fluoride (PVF), polyvinylidene fluoride (PVDF), ethylene-terafluoethylene (ETFE), fluorinated ethylene-propylene (FEP), perfluoroalkoxy (PFA) and polychlorotrifluoroethane (PCTFE)), acrylics (e.g., poly(methyl methacrylate)), silicones (e.g., silicone polyesters), polyvinyl chloride PVC, nylon, acylonitrile butadiene styrene (ABS), as well as multilayer laminates and co-extrusions of these materials. A typical thickness of a sealing sheet is between about 25 microns and 2,540 microns or, more specifically, between about 125 microns and 1,270 microns, though other thicknesses may be used as well.

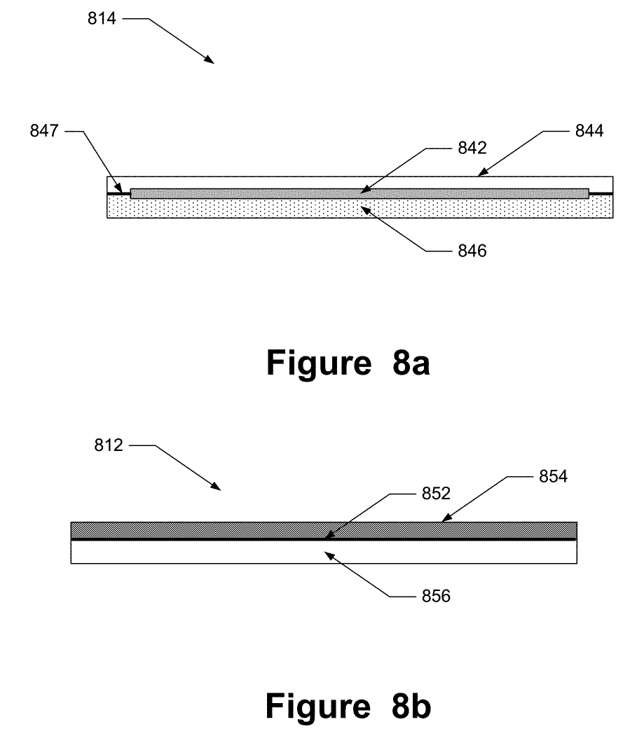

In some embodiments, the flexible top sheet 112 is a transparent multi-layer film, including a transparent barrier film between two transparent polymer layers. The barrier may be, for example, an aluminum oxide (AlOₓ) or silicon oxide (SiOₓ) film. An example of a commercially available barrier film is 3M™ Ultra Barrier Solar Film. In one example, the flexible top sheet may have fluoropolymer as the outermost film of the module, a transparent barrier film, and a PET film facing the module interior. The transparent barrier film is a very thin film, and may be less than 1 micron thick, or less than 1% of the total flexible top sheet thickness. An example of a flexible top sheet is described below with reference to FIG. 8a.

In certain embodiments, the flexible bottom sheet 114 is a multi-layer flexible bottom sheet including one or more interior layers and a back outermost layer. The flexible bottom sheet 114 may also have a moisture barrier disposed between the one or more interior layers and the back outermost layer. A moisture barrier can be, for example, an electrically isolated aluminum foil. Examples of an interior layer include PET. The back outermost layer is a weatherable material and may be fluoropolymer, including but not limited to polyvinyl fluoride (PVF), polyvinylidene fluoride (PVDF), ethylene-terafluoethylene (ETFE), fluorinated ethylene-propylene (FEP), perfluoroalkoxy (PFA) and polychlorotrifluoroethane (PCTFE). Other weatherable materials may be used in addition to or instead of a fluoropolymer, including polyethylene terephthalate (PET), silicone polyesters, chlorine-containing materials such as polyvinyl chloride (PVC), plastisols and acrylics. In certain embodiments, any material that meets UL 1703 requirements is used. UL 1703, edition 3, as revised April 2008, is incorporated by reference herein.

In one example, the back layer is a weatherable PET material. In some embodiments, the one or more interior layers of a multi-layer flexible bottom sheet include an insulation sheet, such as PET. An example of a flexible bottom sheet is described below with reference to FIG. 8b.

The module 100 includes the edge seal 106 that surrounds and, together with the flexible top sheet 112 and the flexible bottom sheet 114, seals the photovoltaic cells 102 within the sealed space 104. The edge seal 106 may prevent moisture from penetrating towards the photovoltaic cells 102. The edge seal 106 may be made from one or more organic or inorganic materials that have low inherent water vapor transmission rates. In certain embodiments, a portion of the edge seal 106 that contacts electrical components (e.g., bus bars, diodes, return lines) of module 100 is made from a thermally resistant polymeric material. The edge seal 106 may also secure flexible top sheet 112 with respect to the flexible bottom sheet 114. In certain embodiments, the edge seal 106 determines some of the boundaries of the sealed space 104.

In some embodiments, the module 100 may be manufactured using one or more lamination procedures in which aspects of the module 100 may be heated and pressed. For example, the pressing may be performed by an inflatable bladder, and such lamination may heat the edge seal such that the sealed space 104 is formed in the module 100.

The electrical components and configurations of the module 100 will now be discussed. In FIGS. 1 and 2, the eight photovoltaic cells 102 are positioned within the sealed space 104 and electrically interconnected and may or may not be physically overlapping. The photovoltaic cells 102 may be any appropriate solar cells, and in some embodiments, may be flexible photovoltaic cells. A flexible photovoltaic cell is one that can be flexed without damage. Examples of flexible photovoltaic cells include copper indium gallium selenide (CIGS) cells, cadmium-telluride (Cd—Te) cells, amorphous silicon (a-Si) cells, micro-crystalline silicon (Si) cells, crystalline silicon (c-Si) cells, gallium arsenide (GaAs) multi-junction cells, light adsorbing dye cells, and organic polymer cells. A photovoltaic cell has a photovoltaic layer that generates a voltage when exposed to light. The photovoltaic layer may be positioned adjacent to a back conductive layer, which, in certain embodiments, is a thin flexible layer of a metal such as molybdenum (Mo), niobium (Nb), copper (Cu), silver (Ag), and combinations and alloys thereof. The photovoltaic cell may also include a flexible conductive substrate, such as stainless steel foil, titanium foil, copper foil, aluminum foil, or beryllium foil. Additional examples of a flexible conductive substrate include a layer of a conductive oxide or metal over a polymer film, such as polyimide. In certain embodiments, a substrate has a thickness of between about 50 microns and 1,270 microns (e.g., about 254 microns), with other thicknesses also in the scope of the embodiments described herein. The photovoltaic cell may also include a flexible top conductive layer. This layer can include one or more transparent conductive oxides (TCO), such as zinc oxide, aluminum-doped zinc oxide (AZO), indium tin oxide (ITO), and gallium doped zinc oxide. A typical thickness of a top conductive layer is between about 100 nanometers and 1,000 nanometers or, more specifically, about 200 nanometers and 800 nanometers.

The photovoltaic cells are interconnected by a conductor that contacts a front side (i.e., the photovoltaic layer that is exposed to light and generates a voltage) of one cell as well as back side of an adjacent cell to interconnect these two cells in-series. In the example of FIG. 1, an electrical connection between two photovoltaic cells 102 is made using a wire 108. The wires 108 are examples of electrical interconnects. Each wire 108 extends over a front side of one photovoltaic cell and under a back side (as represented by a dotted line) of an adjacent cell to electrically interconnect these two photovoltaic cells in-series. In some embodiments, an interconnect may also function as a current collector; in the example of FIG. 1, the wire 108 collects current generated by the underlying photovoltaic cell. As described further below, the wire 108 is part of an assembly that includes the wire partially embedded in a polymer layer. The shaped wire shown in FIG. 1 is an example of an interconnect and current collector. Other configurations of these components may also be used. For example, in some embodiments, a short piece of thin wire may extend between adjacent cells to interconnect them, with a separate current collector overlying the cells.

The overall electrical arrangement between the photovoltaic cells of the module may be in-series, parallel, or a combination of both. For example, the photovoltaic cells 102 of module 100 may all be electrically connected in-series. This in-series arrangement may result in string of photovoltaic cells having opposite polarities at each end of the string and at opposite ends of the module. In FIG. 1, the string of photovoltaic cells 102 may have one polarity at the first end 122 of the module 100 and the opposite polarity at the second end 124 of the module 100.

In some embodiments, photovoltaic module may include an electrical return line allow electrical connections at a single end of the module. In other embodiments, each of the two ends may have an electrical connection, with no return line.

The bus bar 110 depicted in FIGS. 1 and 2 provides a return line for the string of photovoltaic cells 102. As seen in FIG. 2, the bus bar 110 is positioned between the string of photovoltaic cells 102 and the flexible bottom sheet 114. The bus bar 110 is positioned in the module 100 such that it extends for about substantially the length of the module 100.

The current generated by the module 100 may be transferred to elements external to the module 100, such as other modules in an array of photovoltaic modules, inverters, or a power grid. To form the connections between the module 100 and these external elements, the module may have one or more electrical connectors that are accessed during installation and connected to the external elements, such as electrical connectors of adjacent modules. A module's electrical connectors include electrically conductive elements, such as a metallic wire that may be electrically insulated. An electrical connector may also include, or may be configured to make electrical connections to, standard MC4 photovoltaic connectors or other types of external photovoltaic connectors. For example, a module may have a cable connected to a photovoltaic connector that is electrically connected to the photovoltaic cells such that electricity generated by the cells can be transported to the cable, the photovoltaic connector and to an external electrical connection, such as another module.

The one or more electrical connectors of a flexible photovoltaic module may be electrically connected to the photovoltaic cells that are sealed inside the module and to return lines provided within the module that typically extend along the module. The one or more electrical connectors may be electrically connected to the photovoltaic cells by electrical leads. An electrical lead may have a portion that extends into the sealed space of the module, which may include extending through an edge seal of the module. Electrical leads may be in the form of thin but sufficiently conductive metal strips that may have flat aspect ratios (i.e., their heights may be substantially smaller (e.g., less than 10%) than their widths). In some of the embodiments disclosed herein, the height of an electrical lead may be 0.1 millimeters or 0.125 millimeters, while the width may be 12 mm. An electrical lead may be positioned within a module during manufacturing such that one portion of an electrical lead is located within a sealed space of the module with another portion extending through and outside the sealed space so that it may electrically connect with an electrical connector.

For example, as can be seen further in FIG. 1, the module 100 includes a first external electrical connector 116 and a second external electrical connector 118 that are both located at the first end 122 of the module 100. The first external electrical connector 116 has a first electrical lead 117 that extends through the edge seal 106, into the sealed space 104, and is electrically connected to the first photovoltaic cell 102. The second external electrical connector 118 has a second electrical lead 119 that extends through the edge seal 106, into the sealed space 104, and is electrically connected to the further photovoltaic cell 102 through the bus bar 110, which serves as the electrical connection pathway between these two elements as discussed above.

If present, the bus bar 110 may be solid metal band or strip, or a non-monolithic conductor that includes interlaced metallic strands that are interlaced as described in U.S. patent application Ser. No. 15/826,316, filed Nov. 29, 2017, incorporated by reference herein. In some embodiments, the bus bar extends substantially the length of the photovoltaic module (substantially here means within 15% of the length); some example lengths of the modules include about 1.6 meters to about 6 meters. The thickness of the bus bar (as measured in the y-axis) may be about 0.5 millimeters or less. For thin modules having a thickness of 1 millimeter or less, the bus bars are less than this overall module thickness, such as about 0.5 millimeters. The width of the bus bar may (as measured in the x-axis), in some embodiments, be about 4 millimeters or about 5 millimeters.

FIG. 3 shows a front view 301 and a back view 303 of a wire assembly disposed on the top side of a photovoltaic cell. The front view 301 shows the front, or light facing, side of the photovoltaic cell including a conductive transparent top layer 307, and back view 303 shows a metallic substrate 311 supporting a thin film solar cell stack.

The wire assembly includes the wire 308 and a wire carrier. In the depicted embodiment, wire 308 is configured as a current collector to collect current generated by a single photovoltaic cell and as an electrical interconnect to electrically connect the cell to another cell in a photovoltaic module. In other module configurations, the wire may be configured only as a current collector or only as an interconnect.

Referring to front view 301, a current collector portion 319 of wire 308 is configured to directly contact the top layer 307 of a photovoltaic cell, e.g., top transparent conductive layer, and collect current generated from the cell. The wire 308 may be a thin, highly conductive metal wire. Examples of wire metals include copper, aluminum, nickel, chrome or alloys thereof. In some embodiments, a nickel coated copper wire is used. In certain embodiments wire having a gauge of 24 gauge-56 gauge is used. The wire carrier includes a front strip 315 and a back strip 317.

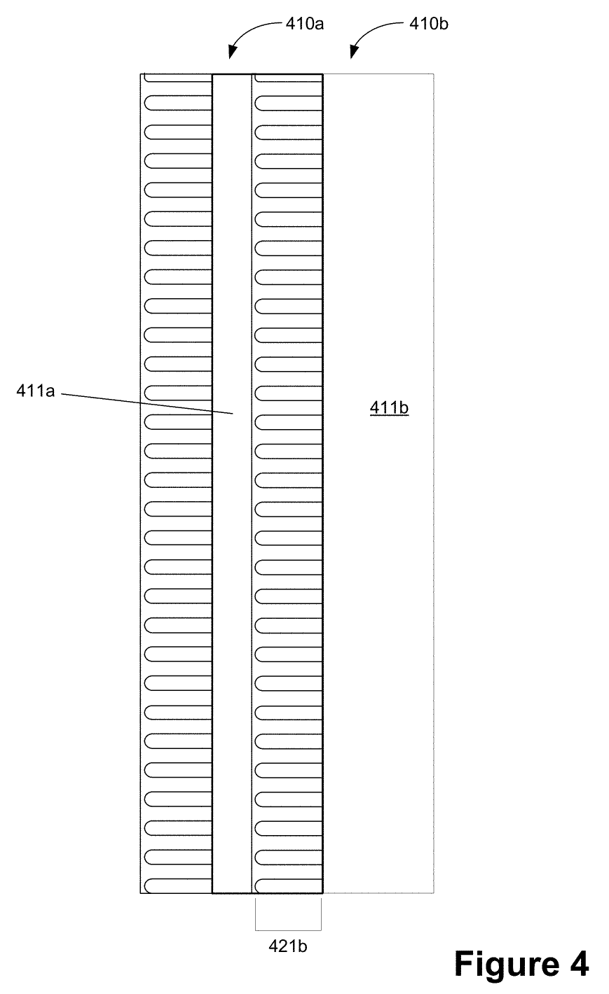

The back view 303 depicts a metallic substrate 311 that supports the photovoltaic stack (which can include p- and n-type semiconductor layers and top and bottom electrode or electrical contact layers) and interconnect portion 321 of the wire 313. The back strip 317, which overlies the interconnect portion 321 of the wire 308 as shown in the back view 303, is an insulating carrier for the wire 308. In back view 303, the conductive side of interconnect portion 321 faces down, able to make contact with a metallic substrate of an adjacent cell. An example is depicted in FIG. 4, which shows the backsides of cells 410a and 410b including metallic substrates 411a and 411b. A wire interconnect 421b of cell 410b overlies a metallic substrate 411a of cell 410a, thereby electrically connecting the cells 410a and 410b.

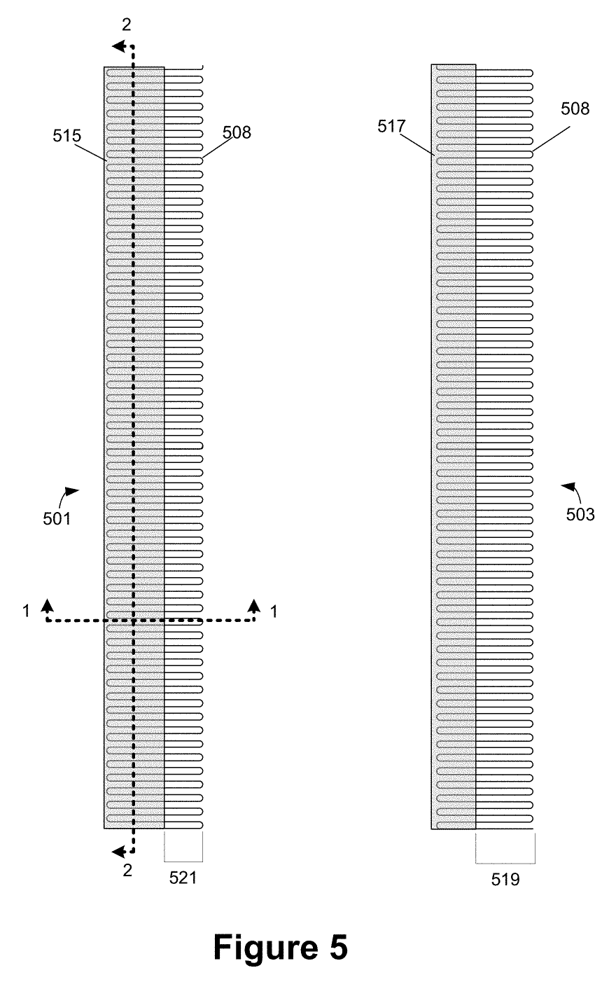

FIG. 5 shows a front view 501 and a back view 503 of a strip of a wire assembly including a wire 508 and front and back strips 515 and 517, respectively. The front view 501 shows the wire 508 and the front strip 515, which overlies a portion of the wire 508. For clarity, the back strip 517 is not depicted in the front view 501. An exposed portion 521 of the wire 508 is configured to interconnect photovoltaic cells as depicted in FIG. 4. The back view 503 shows the wire 508 and the back strip 517, which overlies a portion of the wire 508. An exposed portion 519 of the wire 508 is configured to contact the top layer of a cell (e.g., a TCO layer) and act as a current collector.

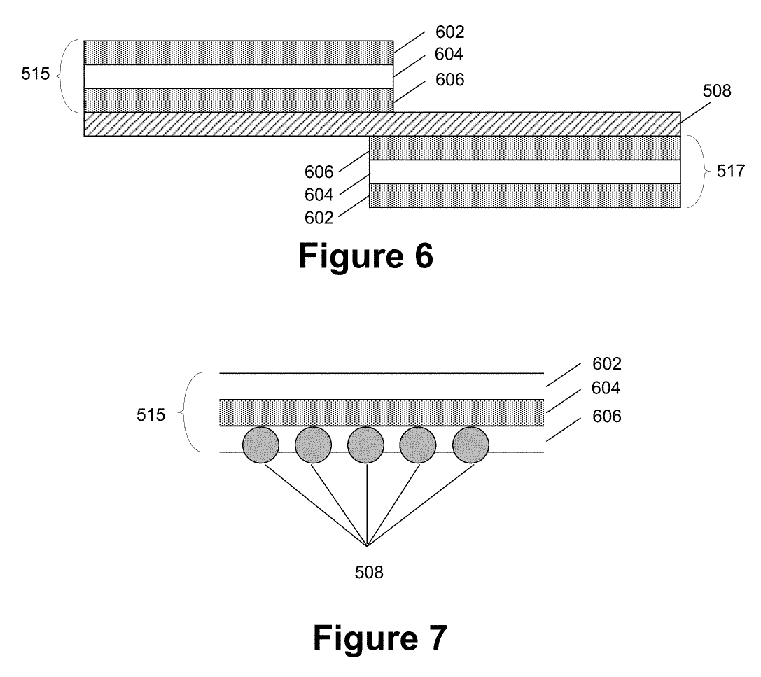

FIG. 6 depicts a cross-sectional view of a wire assembly along line 1-1 of FIG. 5, according to certain embodiments. The wire assembly includes the top strip 515, the bottom strip 517, and the wire 508. In the example embodiment, the top strip 515 and the bottom strip 517 each include three polymer films: a first polymer film 602, a second polymer film 604, and a third polymer film 606. In some embodiments, the first polymer film contacts the second polymer film and the second polymer film contacts the third polymer film. In other embodiments, there is a layer of adhesive between the first polymer film and the second polymer film. In further embodiments, there is a layer of adhesive between the second polymer film and the third polymer film. Note that FIG. 6 is a schematic representation of a wire assembly, and that in some embodiments, the wire 508 is embedded in the third polymer film of the top strip and/or the bottom strip. In the depicted embodiment, the top strip 515 and the bottom strip 517 include the same polymers arranged in the same order (the innermost polymer layer being the third polymer film 606, etc., but in other embodiments, the top strip and the bottom strip have different polymer film stacks. Further, in some embodiments, one or both of the top strip and the bottom strip does not include first polymer 602. In FIG. 6, the top strip 515 and bottom strip 517 overlap in a lateral direction. In different embodiments, the amount of this overlap is variable, and in some embodiments, the top strip 515 and the bottom strip 517 do not overlap. The dimensions of the top strip (i.e., the thicknesses and widths of the first polymer film, the second polymer film, and the third polymer film) and the bottom strip are the same in some embodiments, and different in other embodiments.

FIG. 7 depicts a cross-sectional view of a wire assembly along line 2-2 of FIG. 5, according to certain embodiments. FIG. 7 shows the wire 508 embedded in third polymer film 606 of the top strip. The top strip 515 also includes first polymer film 602 and second polymer film 604. A surface of the wire facing away from second polymer film 604 is exposed. In some embodiments, the exposed surface of the wire makes electrical contact with a layer of material underlying the third polymer film, such as a transparent conducting oxide layer.

In certain embodiments, the polymer films 602, 604, and 606 are thermoplastic polymer films. For example, the polymer films may be thermoplastic polymer films such as polyethylene terephthalate (PET) films, poly(methyl methacrylate) (PMMA) films, fluorinated ethylene propylene (FEP) films, ethylene tetrafluoroethylene (ETFE) films, polycarbonate films, polyamide films, polyetheretherketone films (PEEK) films, low density polyethylene films, low density urethane films, or low density polymer (with ionomer functionality) films (e.g., poly(ethylene-co-methacrylic acid) (Surlyn™)). In some embodiments, the second polymer film is a polyethylene terephthalate (PET) film, a poly(methyl methacrylate) (PMMA) film, a fluorinated ethylene propylene (FEP) film, an ethylene tetrafluoroethylene (ETFE) film, or a polycarbonate film. The first polymer film and the third polymer film are the same type of polymer film in some embodiments, and in other embodiments, they are different types of polymer film. In some embodiments, the first and the third polymer films are a low density polyethylene film, a low density urethane film, or a low density polymer (with ionomer functionality) film. In a specific embodiment, the first and the third polymer films are films of poly(ethylene-co-methacrylic acid) (Surlyn™).

In some embodiments, the first, second, and third polymer films are thermoplastic polymer films, with the melting point temperature of the second thermoplastic polymer film being greater than the melting point temperatures of the first and the third polymer films. This difference in melting point temperatures allows the serpentine wire to be heated in the fabrication process of a wire assembly and be embedded in the third polymer film but not the second polymer film.

For example, in a specific embodiment, the third polymer film is a poly(ethylene-co-methacrylic acid) film and the second polymer film is a polyethylene terephthalate film. Polyethylene terephthalate has a melting point of greater than about 250° C., and poly(ethylene-co-methacrylic acid) has a melting point of about 90° C. These melting point temperatures vary with the processing and manufacturing methods of the polymer films. This difference in melting point temperatures allow a wire heated to about 120° C., for example, to be embedded in the third polymer film but not the second polymer film. The second polymer film acts as a barrier through which the heated wire will not pass. In some embodiments, the second (middle) polymer film has a melting temperature of at least 160° C., or at least 180° C., or at least 200° C., with the first and third polymer films having a melting temperature of less than 140° C., or of less than 120° C., or less than 100° C.

In some embodiments, the wire is in contact with the second polymer film, as depicted in FIG. 7; in other embodiments, the wire is not in contact with the second polymer film. In some embodiments there is a layer of adhesive between the poly(ethylene-co-methacrylic acid) film and the polyethylene terephthalate film. In some embodiments the layer of adhesive is a layer of polyurethane adhesive. In some embodiments the thickness of the layer of adhesive is about 0.5 microns to 10 microns.

In other embodiments the first polymer film and/or the third polymer film are an adhesive material. In other embodiments a non-polymeric adhesive material is used in place of the first polymer film and/or the third polymer film.

In certain embodiments, at least the top polymer film (polymer film 602 in FIG. 6) is an adhesive material. If present, the bottom polymer film (polymer film 604 in FIG. 6) may or may not be an adhesive material according to various embodiments. In some embodiments, it may be an adhesive to facilitate holding wire 508.

An adhesive material is a material that will flow around module components under application of an energy (e.g., heat, pressure, UV radiation) and then set once the energy is removed. The adhesives in the modules herein are also optically transparent and thermally stable over the operating temperature of the module.

In some of these embodiments, the adhesive material is a silicone-based polymer. Some examples of such adhesive materials include the following materials available from Dow Corning in Midland, Mich.: two part translucent heat cure adhesive (part number SE1700), and two part fast cure low modulus adhesive (part numbers JCR6115 and JCR 6140). In some embodiments the adhesive material is a thermoset polymer material. Examples of such adhesive materials include polyurethanes, epoxies, silicones, acrylics and/or combinations of these materials. A further example of such an adhesive material is a reactively functionalized polyolefin (e.g., with functional acrylate groups). In further embodiments the adhesive material has pressure sensitive adhesive (PSA) characteristics and may be cross-linked with ultra-violet light, an electron beam, or thermal energy. A PSA may be a non-Newtonian PSA or thixotropic PSA. It may include one or more of the following materials: a UV-reactive styrenic block copolymer, a cationic curing epoxy-functional liquid rubber, a saturated polyacrylate, an acrylate monomer, and an acrylate oligomer, and an acrylated polyester. In some embodiments, the first polymer film and the third polymer film each have a thickness of no more than about 25 microns (or 1 mil).

FIG. 8a shows an example of a multi-layer flexible bottom sheet 814. In the example of FIG. 8a, the flexible bottom sheet 814 includes a flexible moisture barrier 842 disposed between an inner sheet 844 and an outermost layer 846. A seal 847 extends around the moisture barrier. In the example of FIG. 8a, the flexible moisture barrier 842 may, be for example, a thin metallic sheet with the inner sheet 844, outermost layer 846 and seal 847 together electrically isolating the flexible moisture barrier 842 to prevent shorting between the photovoltaic cells in the assembled module and the flexible moisture barrier 842. The multi-layer flexible bottom sheet 814 depicted in FIG. 8a is an example of a multi-layer flexible bottom sheet. According to various embodiments, the flexible moisture barrier is not present, for example. In certain embodiments, the outermost layer 846 extends towards may cover the edges of the inner sheet 844. Also, in some embodiments, the flexible bottom sheet may be a single layer film.

In certain embodiments, the inner sheet is or contains a thermoplastic adhesive. The inner sheet may be between 25-150 microns in some embodiments. For example, the inner sheet may be a 100 micron thermoplastic olefin that acts as an adhesive to bond module components together.

In some embodiments, an insulation sheet (such as a PET sheet) is provided between the inner sheet and the outermost layer. Non-limiting examples of insulation materials include thermal polymer olefins (TPO) and non-olefin thermoplastic polymers, including polybutylene, polyethylene terephthalate (PET), polybutylene terephthalate (PBT), polystyrene, polycarbonates, ethylene-vinyl acetate (EVA), fluoropolymers, acrylics, including poly(methyl methacrylate), or silicones, as well as multilayer laminates and co-extrusions, such as PET/EVA laminates or co-extrusions. In other examples, the insulation sheet is a nylon, acylonitrile butadiene styrene ABS), polybutylene terephthalate (PBT), (polycarbonate (PC), PPS (polyphenylene sulfide (PPS), or polyphenylene oxide (PPO). Other examples of polyolefins that may be used include polyethylene and polypropylene.

As described above, the outermost layer is a weatherable material such PVF, PVDF, ETFE, FEP, PFA, PCTFE, silicone polyesters, PVC, plastisols, acrylics, and a weatherable PET material.

In the example of FIG. 8a, the seal 847 includes a bond between the outermost layer 846 and the inner layer 844. In some embodiments, it is a permanent seal and/or an irreversible seal. According to various embodiments, the seal is at least 0.5 mm, 1 mm or 2 mm wide, though other dimensions may be appropriate. The bond between outermost layer 846 and inner layer 844 may be an adhesive bonding, a fusion bonding, a welding, a solder bond, or a mechanical fastening. As used herein, the term “permanent seal” refers to a seal that has a resistance to rupture greater than a frangible seal. As used herein, “irreversible seal” refers to seal that is unbreakable by exposure to atmospheric heat and weather conditions, and generally must be deliberately tampered with to be broken. In certain embodiments, the seal includes covalent bonding, e.g., between an adhesive and the outermost layer and/or inner sheet, or between the inner sheet and outermost layer.

If an adhesive material is used for a seal, it may be a thermoplastic adhesive, a liquid adhesive, a curable adhesive, or any other type of adhesive that creates an irreversible seal, is resistant to peeling and has good moisture resistance. Thermoplastic adhesives that may be used include acrylics, silicone resins, polyamines and polyurethanes. In certain embodiments, the adhesive may also be used to adhere the insulation sheet and back layer to the moisture barrier. In certain embodiments, one of the layers may be formed by extrusion coating or casting, e.g., on a chemically primed surface.

FIG. 8b shows an example of a multi-layer flexible top sheet 812. In the example of FIG. 8b, the multi-layer flexible top sheet 812 includes an outermost layer 854, a barrier film 852 such as an AlOₓ or SiOₓ film and an inner layer 856. Transparent polymer layers as described above may be employed for the outermost layer 854 and the inner layer 856. In one example, the outermost layer 854 is a transparent ETFE film of between 25 and 50 microns, and the inner layer 856 is a PET layer of between 100 and 150 microns. In some embodiments, the flexible top sheet may be a single layer material.

FIGS. 8a and 8b provide examples of flexible bottom sheets and flexible top sheets, respectively. In some embodiments, an adhesive sheet is provided between the described layers of the multi-layer stacks of the bottom and/or top sheet prior to lamination. For example, webs or sheets of PET, adhesive and PVF may be provided to assemble a PET/adhesive/PVF pre-laminate stack. The pre-laminate stack assembly (which may also including a moisture barrier) may then be laminated in to form a laminate stack, which may then be assembled with the photovoltaic cells, wire assemblies, flexible top sheet, and other module components. Similarly, a flexible top sheet may be formed from an ETFE/adhesive/barrier/adhesive/PET stack. In some embodiments, these pre-laminate stacks may be assembled prior to lamination with the other module components and then laminated.

The adhesives are generally thermoplastic adhesives or pressure sensitive adhesives. Specific examples of adhesives include Surlyn® Ionomer Adhesives from DuPont™ having prelamination thicknesses of 12.5 microns-150 microns. It should be noted that these films are significantly thinner than encapsulant sheets, which are typically 200-800 microns thick. As such, the adhesives are difficult to handle as a free-standing film. In some embodiments, the thickness of an adhesive that is the innermost layer of a flexible bottom sheet may be characterized as an average thickness across cross-section of a module. The average thickness may be 12.5 to 150 microns, or no more than 150 microns, in some embodiments.

In some embodiments, the adhesive from one or more of the wire carriers, the flexible top sheet, and the flexible bottom sheet binds the module components together under lamination. In some embodiments, the flexible bottom sheet and the wire carrier have a total of between 125-250 microns of adhesive in the prelamination stack. As described above, in some embodiments, each of the top and bottom strips of a wire carrier includes two layers of adhesive (the first and third polymeric films).

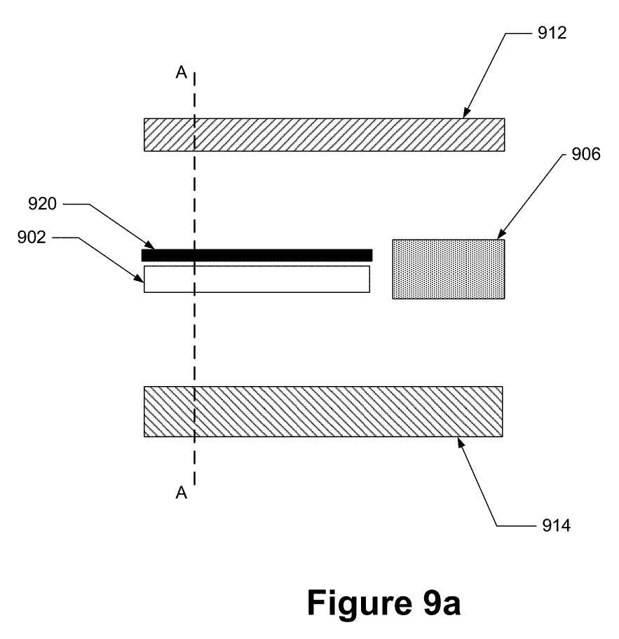

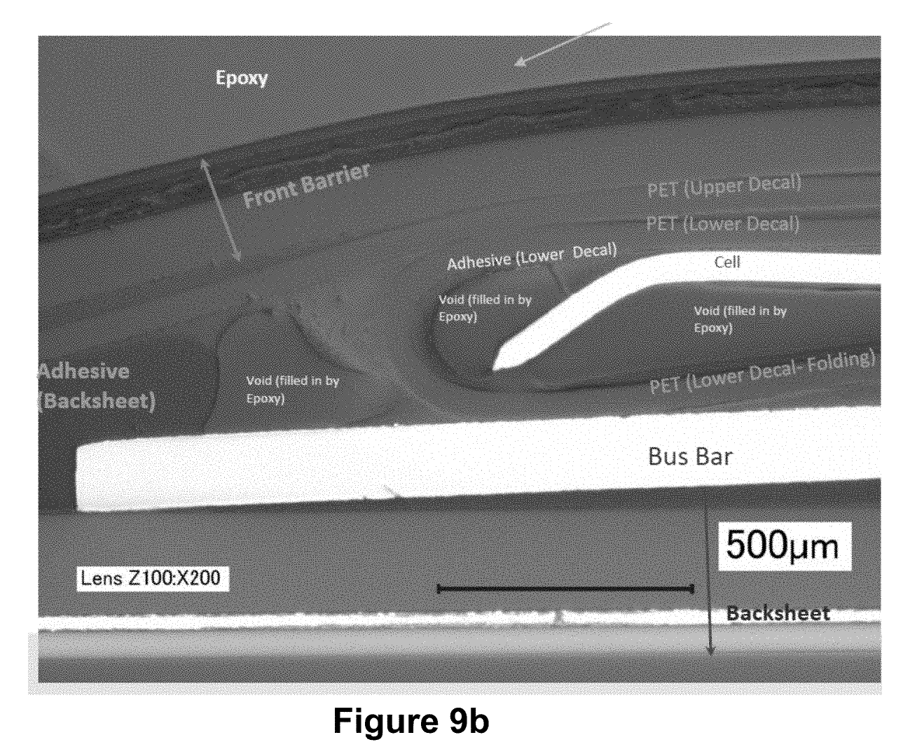

FIG. 9a depicts a schematic of a cross-sectional, exploded view of a portion of a module. The material stack of the module is shown in FIG. 9a, and includes a flexible top sheet 912, a flexible bottom sheet 914, an edge seal 906, a flexible photovoltaic cell 902, and a wire assembly 920. The flexible bottom sheet 914 and the flexible top sheet 912 form the bottom and top surfaces of the module as depicted in FIG. 1, and generally extend across the entire module, or at least the entirety of the photovoltaic area. Other components, such as a bus bar, diodes, etc., may be present in the module. However, in some embodiments, the flexible bottom sheet 914 and the flexible top sheet 912 are the only material layers that extend across the entire photovoltaic area; notably there are no encapsulant layers disposed between the wire assemblies and the flexible top sheet or between the photovoltaic cells and the flexible bottom sheet. This is distinct from modules that include an integral or monolithic encapsulant layer between the photovoltaic cells and the flexible top sheet and/or between the photovoltaic cells and the flexible bottom sheet.

FIG. 9b is an annotated image of a cross-section taken along a line A-A as shown in FIG. 9a. A bus bar, not depicted in FIG. 9a, is shown in the image of FIG. 9b. In the image, the upper and lower strips of the wire carrier are labeled “upper decal” and “lower decal,” respectively. As indicated in the annotations, “epoxy” is not part of the module construction, but an artifact of the cross-section process in which the sample is encapsulated by liquid epoxy, which holds the other components in place on solidification. As a result, voids that are present are often filled with epoxy. Adhesive from the flexible bottom sheet (labeled backsheet in FIG. 9b) and adhesive from the decal binds the components together.

Notably, the voids within the module are significantly smaller than 50 mm² and do not affect performance. In some embodiments, the module includes no voids less than 50 mm², less than 20 mm², or less than 1 mm². As a result, performance issues due to excessive internal light reflections are not present. It should also be noted that at least in some parts of the module, the middle polymer layer (PET in the example of FIG. 9b) of the wire carrier directly contacts the flexible top sheet.

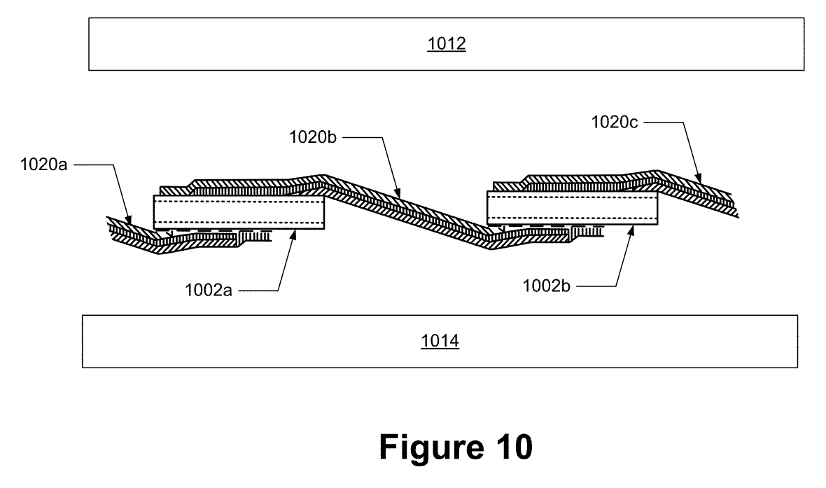

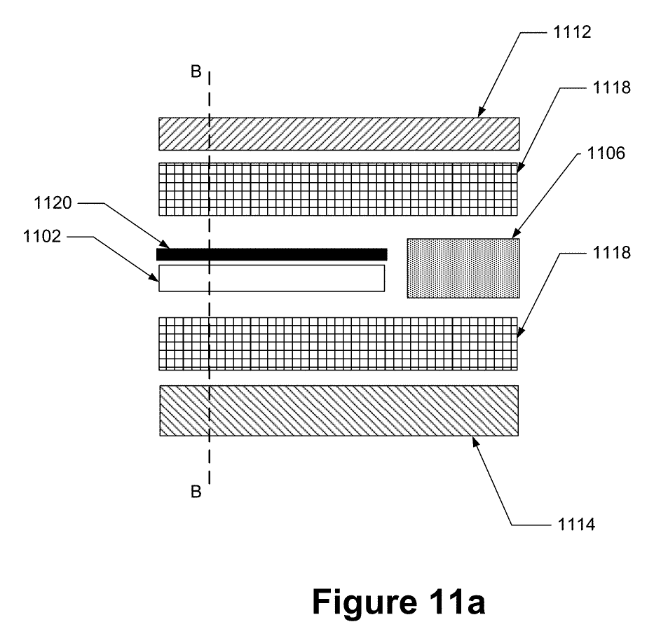

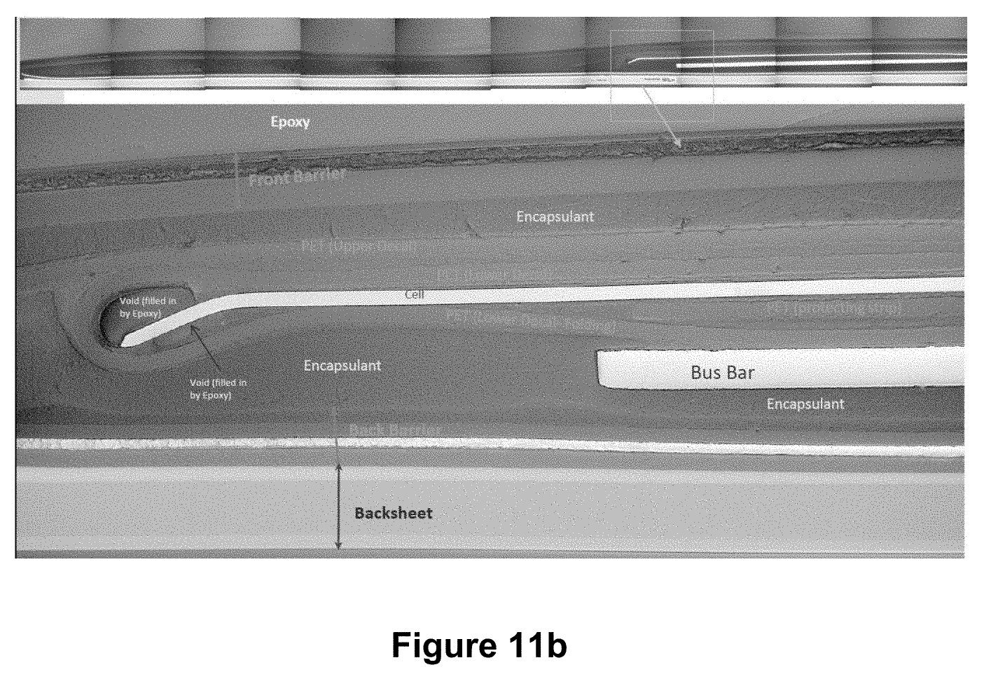

FIG. 10 shows a schematic of an exploded view of a portion of a module stack according to certain embodiments. As depicted in FIG. 10, wire carriers 1020a, 1020b, and 1020c, which interconnect photovoltaic cells 1002a and 1002b with each other and adjacent cells (not shown), form discrete units within the module. Further, the wire carriers 1020a, 1020b, and 1020c directly contact the flexible top sheet 1012 and the flexible bottom sheet 1014. The module examples depicted in FIGS. 9a and 9b can be compared with those in FIGS. 11a and 11b. In FIG. 11a, a module stack similar to that shown in FIG. 9a is depicted, with an encapsulant sheet 1118 provided between the photovoltaic cells 1102 and each of a flexible top sheet 1112 and a flexible bottom sheet 1114. An edge seal 1106 and wire carrier 1120 is also shown. The encapsulant sheets are typically between 100-500 microns thick, making the resulting module of FIG. 11a 200-1000 microns thicker than the module of FIG. 9a.

FIG. 11b is an annotated image of a cross-section taken along a line B-B as shown in FIG. 11a. A bus bar, not depicted in FIG. 11a, is shown in the image of FIG. 11b. As in FIG. 9b, in the image of FIG. 11b, the upper and lower strips of the wire carrier are labeled “upper decal” and “lower decal,” respectively, and the bottom sheet is labeled “back sheet.” Unlike in FIG. 9b, there is a continuous layer of encapsulant disposed between the cell and the bottom sheet, as well as between the cell and the top sheet. These encapsulant layers extend over the photovoltaic area. As a result, the layer structure is more even, with less variation across the module. As noted above a module as described in FIG. 9a may be, for example, between 200-1000 microns thinner than that in FIG. 11a. In some embodiments, the module is no more than 0.4 mm thick.

Although the foregoing invention has been described in some detail for purposes of clarity of understanding, it will be apparent that certain changes and modifications may be practiced within the scope of the appended claims. It should be noted that there are many alternative ways of implementing the processes, systems and apparatus of the present invention. Accordingly, the present embodiments are to be considered as illustrative and not restrictive, and the invention is not to be limited to the details given herein.

What is claimed is:

1. A photovoltaic module comprising:
a transparent flexible top sheet;
a flexible bottom sheet;
a plurality of photovoltaic cells disposed between the transparent flexible top sheet and flexible bottom sheet; and
a plurality of individual wire assemblies overlaying the photovoltaic cells to interconnect the photovoltaic cells;
wherein there is no encapsulant separating the plurality of individual wire assemblies from the transparent flexible top sheet and the flexible bottom sheet.

2. The photovoltaic module of claim 1, wherein each of the individual wire assemblies comprises a layer of a first polymeric material having a melting temperature greater than 160° C. between second and third thermoplastic polymeric layers having melting temperatures less than 140° C.

3. The photovoltaic module of claim 2, wherein the second and third thermoplastic polymeric layers are polyolefins.

4. The photovoltaic module of claim 1, wherein at least some of the individual wire assemblies directly contact the transparent flexible top sheet.

5. The photovoltaic module of claim 1, wherein at least some of the individual wire assembles directly contact the flexible bottom sheet.

6. The photovoltaic module of claim 1, wherein the module includes no void spaces having a cross-sectional area of greater than 50 mm².

7. The photovoltaic module of claim 1, wherein the flexible bottom sheet is a multi-layer flexible sheet, having an innermost layer that faces the photovoltaic cells and an outermost layer that forms an outermost layer of the photovoltaic module.

8. The photovoltaic module of claim 7, wherein the innermost layer is a thermoplastic polymeric layer having a melting temperature less than 140° C.

9. The photovoltaic module of claim 8, wherein the innermost layer is between 50 microns and 150 microns thick.

10. The photovoltaic module of claim 8, wherein the innermost layer has an average thickness across a cross-section of the module of no more than 150 microns.

11. The photovoltaic module of claim 8, wherein at least some of the innermost layer directly contacts one or more individual wire carriers.

12. The photovoltaic module of claim 1, wherein the module has a thickness of no more than 0.4 mm.

13. A photovoltaic module comprising:
a transparent flexible top sheet;
a flexible bottom sheet, comprising an innermost adhesive layer having a thickness of between 12.5 and 150 microns;
a plurality of photovoltaic cells disposed between the transparent flexible top sheet and flexible bottom sheet; and
a plurality of individual wire assemblies overlaying the photovoltaic cells to interconnect the photovoltaic cells,
wherein there innermost layer of the flexible bottom sheet directly contacts at least some of the plurality of individual wire assemblies.

14. The photovoltaic module of claim 13, wherein the module includes no void spaces having a cross-sectional area of greater than 1 mm².

15. The photovoltaic module of claim 13, wherein at least some of the individual wire assemblies directly contact the transparent flexible top sheet.
